(19) United States
(12) Patent Application Publication
(10) Pub. No.: US 2025/0015100 A1
(43) Pub. Date: Jan. 9, 2025

(54) IMAGE SENSOR

(71) Applicant: Samsung Electronics Co., Ltd., Suwon-si (KR)

(72) Inventor: Eunsub Shim, Suwon-si (KR)

(21) Appl. No.: 18/662,034

(22) Filed: May 13, 2024

(30) Foreign Application Priority Data
Jul. 3, 2023 (KR) 10-2023-0085616

(51) Int. Cl. H01L 27/146

(52) U.S. Cl. CPC H01L 27/14603; H01L 27/1461; H01L 27/14614; H01L 27/1464

(57) ABSTRACT

An image sensor includes a photodiode disposed in a substrate and including an n-type impurity region, wherein the n-type impurity region is doped with n-type impurities, a transfer gate (TG) structure partially buried in the substrate and disposed on the n-type impurity region, a recess disposed at an upper surface of the substrate and being spaced apart from the TG structure, a floating diffusion (FD) region disposed under the recess and doped with n-type impurities, and an impurity region disposed at a portion of the substrate between the TG structure and the recess and doped with p-type impurities. An upper surface of the FD region is lower than an upper surface of the impurity region.

### CROSS-REFERENCE TO RELATED APPLICATION

This application claims priority under 35 USC § 119 to Korean Patent Application No. 10-2023-0085616, filed on Jul. 3, 2023 in the Korean Intellectual Property Office (KIPO), the contents of which are herein incorporated by reference in their entirety.

### BACKGROUND

### 1. Field

Example embodiments relate to an image sensor.

### 2. Description of the Related Art

An image sensor includes pixels, and an approach to enhance the effectiveness of transferring charges from a photodiode within each pixel to a floating diffusion (FD) region is desirable.

### SUMMARY

Example embodiments provide an image sensor having improved characteristics.

According to an aspect of the present disclosure, an image sensor includes a photodiode disposed in a substrate and including an n-type impurity region, wherein the n-type impurity region is doped with n-type impurities, a transfer gate (TG) structure partially buried in the substrate and disposed on the n-type impurity region, a recess disposed at an upper surface of the substrate and being spaced apart from the TG structure, a floating diffusion (FD) region disposed under the recess and doped with n-type impurities, and an impurity region disposed at a portion of the substrate between the TG structure and the recess and doped with p-type impurities. An upper surface of the FD region is lower than an upper surface of the impurity region.

According to an aspect of the present disclosure, an image sensor includes a first n-type impurity region in a substrate, a transfer gate (TG) structure partially buried in an upper portion of the substrate in a vertical direction perpendicular to an upper surface of the substrate and disposed on an upper surface of the first n-type impurity region, a second n-type impurity region in the substrate, wherein the second n-type impurity region is disposed over and is spaced apart from the first n-type impurity region in the vertical direction in the substrate, and wherein the second n-type impurity region is spaced apart from the TG structure in a horizontal direction parallel to the upper surface of the substrate, and a p-type impurity region in the upper portion of the substrate and doped with p-type impurities. An upper surface of the second n-type impurity region is lower than a lower surface of the p-type impurity region.

According to an aspect of the present disclosure, an image sensor includes a microlens on an upper surface of a substrate, a color filter array layer disposed between the upper surface of the substrate and the microlens, a first n-type impurity region in the substrate, a transfer gate (TG) structure partially buried in a lower portion of the substrate in a vertical direction perpendicular to the upper surface of the substrate, wherein the TG structure is disposed under the first n-type impurity region, a second n-type impurity region disposed in the substrate, wherein the second n-type impurity region is positioned lower than and spaced apart from the first n-type impurity region in the vertical direction, and wherein the second n-type impurity region is spaced apart from the TG structure in a horizontal direction parallel to the upper surface of the substrate, and a p-type impurity region disposed in the substrate and positioned lower than the second n-type impurity region. An upper surface of the second n-type impurity region is higher than an upper surface of the p-type impurity region.

In the pixel included in the image sensor in accordance with example embodiments, the distance between the light sensing element and the FD region may decrease to enhance the charge transfer efficiency, so that the image sensor may have improved electrical characteristics.

### BRIEF DESCRIPTION OF THE DRAWINGS

FIG. 1 is a plan view illustrating a pixel included in an image sensor, and FIG. 2 is a cross-sectional view taken along line A-A′ of FIG. 1.

FIGS. 3 and 4 are cross-sectional views illustrating a method of forming a pixel of an image sensor in accordance with example embodiments.

FIG. 5 is a plan view illustrating a pixel included in an image sensor, and FIG. 6 is a cross-sectional view taken along line A-A′ of FIG. 5.

FIG. 7 is a plan view illustrating a pixel included in an image sensor, and FIG. 8 is a cross-sectional view taken along line A-A′ of FIG. 7.

FIG. 9 is a cross-sectional view illustrating an image sensor in accordance with example embodiments.

FIGS. 10 to 16 are cross-sectional views illustrating a method of manufacturing an image sensor in accordance with example embodiments.

### DESCRIPTION OF EMBODIMENTS

Image sensors and methods of manufacturing the image sensors in accordance with example embodiments will be more clearly understood from the following detailed description taken in conjunction with the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

A direction substantially parallel to a surface of a reference substrate or a first substrate and/or a second substrate may be referred to as a horizontal direction, and a direction substantially perpendicular to the surface of the reference substrate or the first substrate and/or the second substrate may be referred to as a vertical direction. The horizontal direction may include first and second directions D1 and D2 substantially perpendicular to each other, and the vertical direction may include a third direction D3.

In the specifications, up vs. down, on and over vs. beneath and under, upper surface vs. lower surface, and upper portion vs. lower portion are relative conceptions to describe opposite sides in the vertical direction, and each wording may have opposite meanings according to the specific parts to be explained in the specifications.

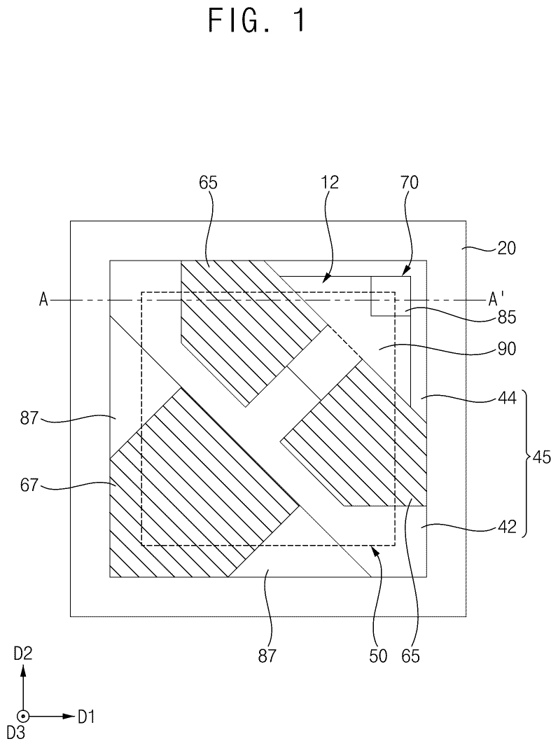

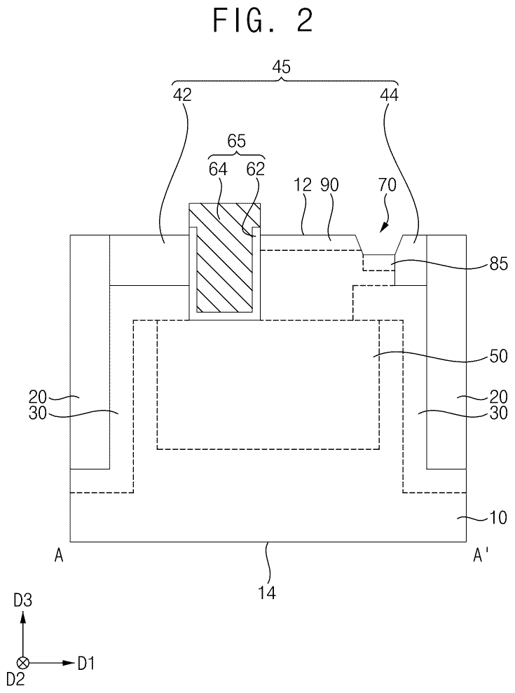

FIG. 1 is a plan view illustrating a pixel included in an image sensor, and FIG. 2 is a cross-sectional view taken along line A-A′ of FIG. 1.

Referring to FIGS. 1 and 2, the pixel may extend in the third direction D3 at least partially through a first substrate 10, and may include a pixel division pattern 20 having a shape of, e.g., a rectangular ring when viewed in a plan view.

FIG. 1 shows that the pixel division pattern 20 has a shape of a rectangular ring including extension portions that extend in the first and second directions D1 and D2, respectively, however, the inventive concept may not be limited thereto. For example, the pixel division pattern 20 may have a shape of an octagonal ring when viewed in a plan view.

In example embodiments, the pixel division pattern 20 may define a pixel region in which the pixels are formed. That is, components of each of the pixels may be formed in a pixel region that may be formed by the pixel division pattern 20. FIG. 1 shows that the pixel region has a shape of a rectangle when viewed in a plan view, however, the inventive concept may not be limited thereto, and may have a shape of, e.g., an octagon.

In example embodiments, the pixel division pattern 20 may include a core extending in the third direction D3 and a shell covering a sidewall of the core. The pixel division pattern 20 may further include a cover layer covering a lower surface and/or an upper surface of the core.

The core may include or may be formed of metal, e.g., aluminum, copper, or tungsten, titanium, or polysilicon, and the shell may include or may be formed of, e.g., silicon oxide.

The first substrate 10 may include or may be formed of silicon, germanium, silicon-germanium, or a II-V group compound semiconductor, such as GaP, GaAs, and GaSb. In example embodiments, a p-type well doped with p-type impurities, e.g., boron, aluminum, or gallium, may be formed partially or entirely in the first substrate 10. In an example embodiment, the p-type well may be lightly doped with a doping concentration less than about 10¹⁵ cm⁻³. In some embodiments, various components of an image sensor may be formed in the p-type well. Such various components may include n-type impurity regions, a floating diffusion region, or a p-type impurity region, which will be describe below. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The first substrate 10 may include first and second surfaces 12 and 14 opposite to each other in the third direction D3, and the first and second surfaces 12 and 14 are shown as upper and lower surfaces, respectively, in FIG. 2.

An isolation structure 45 may be formed at a portion of the first substrate 10 adjacent to the first surface 12, that is, at an upper portion of the first substrate 10. In an example embodiment, a sidewall of the isolation structure 45 may contact an upper sidewall of the pixel division pattern 20, however, the inventive concept may not be limited thereto. The term “contact,” as used herein, refers to a direct connection (i.e., physical touching) unless the context indicates otherwise.

In an example embodiment, the isolation structure 45 may include a first isolation pattern 42 and a second isolation pattern 44. When viewed in a plan view, the first isolation pattern 42 may extend in a direction having an acute angle with respect to the first and second directions D1 and D2 across a central portion of the pixel region. When viewed in a plan view, the second isolation pattern 44 may include first and second extension portions extending in the first and second directions D1 and D2, respectively, at edge portions of the pixel region adjacent to the pixel division pattern 20.

In an example embodiment, each of the first and second isolation patterns 42 and 44 may contact a sidewall of the pixel division pattern 20. In an example embodiment, each of the first and second isolation patterns 42 and 44 may not contact the sidewall of the pixel division pattern 20. A shape and a layout of the isolation structure 45 may not be limited to those shown in FIGS. 1 and 2.

The isolation structure 45 may include or may be formed of oxide, e.g., silicon oxide.

In example embodiments, the pixel may include a light sensing element 50, a transfer gate (TG) structure 65, a transistor, a floating diffusion (FD) region 85, and first and second impurity regions 30 and 90.

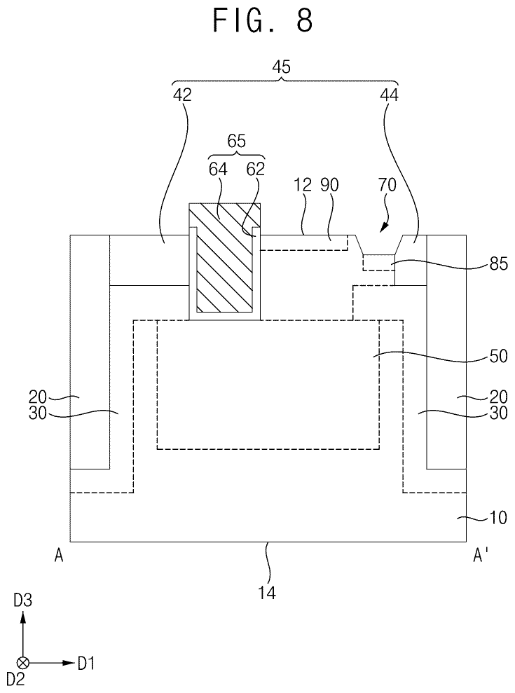

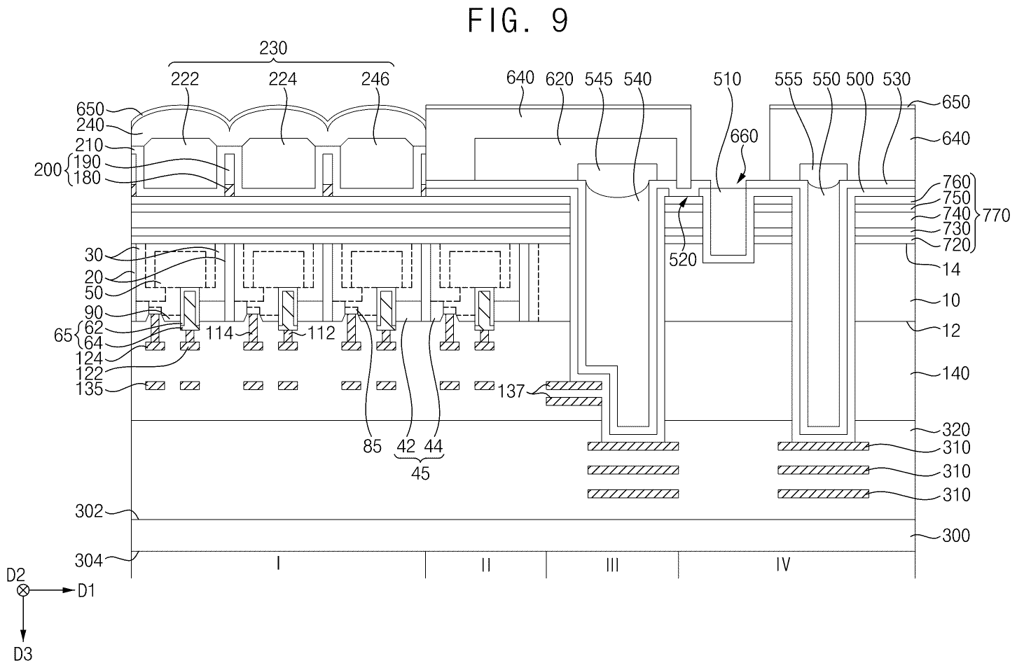

The pixel may further include a color filter, or a microlens, which may be described below with reference to FIG. 9.

In example embodiments, the light sensing element 50 may be a portion of a photodiode (PD). The photodiode may convert an incident light into a charge to generate an electrical signal.

The light sensing element 50 may be a region doped with n-type impurities, e.g., phosphorus or arsenic in the p-type well to form a PN junction at a boundary between the light sensing element 50 and the p-type well. Thus, the light sensing element 50 and the p-type well may collectively form a PN junction diode. In an example embodiment, the light sensing element 50 may have a doping concentration equal to or more than about 10¹⁵ cm⁻³.

In example embodiments, the light sensing element 50 may be disposed at the central portion of the pixel region when viewed in a plan view, and may have a shape of, e.g., a rectangle when viewed in a plan view, however, the inventive concept may not be limited thereto. In example embodiments, a lower surface of the light sensing element 50 may be higher than a lower surface of the pixel division pattern 20.

The first impurity region 30 may cover a portion of the sidewall of the pixel division pattern 20 that is not adjacent to the isolation structure 45 in the horizontal direction, and may also cover the lower surface of the pixel division pattern 20.

In an example embodiment, the first impurity region 30 may include a vertical extension portion extending in the third direction D3 and contacting the sidewall of the pixel division pattern 20, a first horizontal extension portion extending from an upper portion of the vertical extension portion and overlapping an edge portion of the light sensing element 50 in the vertical direction, and a second horizontal extension portion extending from a lower portion of the vertical extension portion and covering the lower surface of the pixel division pattern 20. In an embodiment, the first horizontal extension portion may extend from an upper end of the vertical extension portion, and the second horizontal extension portion may extend from a lower end of the vertical extension portion. However, if the pixel division pattern 20 extends entirely through the first substrate 10 in the third direction D3, the first impurity region 30 may not include the second horizontal extension portion.

In example embodiments, the first impurity region 30 may include or may be doped with p-type impurities, e.g., boron, aluminum, or gallium. The first impurity region 30 may have a doping concentration equal to or more than about 10¹⁸ cm⁻³.

The TG structure 65 may extend through an upper portion of the first substrate 10, and may be adjacent to an upper surface of the light sensing element 50. In an example embodiment, the TG structure 65 may contact the upper surface of the light sensing element 50, however, the inventive concept may not be limited thereto, and may not contact the upper surface of the light sensing element 50. In some embodiments, the TG structure 65 may be partially buried in the upper portion of the first substrate 10.

In an example embodiment, two TG structures 65 spaced apart from each other in the horizontal direction may be disposed in the pixel region, however, the inventive concept may not be limited thereto. In an example embodiment, the TG structure 65 may contact the sidewall of the isolation structure 45 and the sidewall of the pixel division pattern 20. In an example embodiment, the TG structure 65 may not contact the sidewall of the isolation structure 45 and the sidewall of the pixel division pattern 20.

The TG structure 65 may include, e.g., a first gate electrode 64 and a first gate insulation pattern 62 covering a sidewall and a lower surface of the first gate insulation pattern 62. In an example embodiment, the first gate electrode 64 may include a buried portion extending from the first surface 12 of the first substrate 10 downwardly in the third direction D3, and a protrusion portion on the buried portion and having an upper surface higher than the first surface 12 of the first substrate 10, however, the inventive concept may not be limited thereto.

The first gate insulation pattern 62 may include or may be formed of oxide, e.g., silicon oxide, and the first gate electrode 64 may include or may be formed of, e.g., metal, a metal nitride, a metal silicide, or doped polysilicon.

The transistor may be disposed at an edge portion of the pixel region when viewed in a plan view, and may contact the sidewall of the pixel division pattern 20.

The transistor may include a gate structure 67 and a source/drain region 87 at an upper portion of the first substrate 10 adjacent to the gate structure 67, and the gate structure 67 may include a second gate electrode and a second gate insulation pattern covering a sidewall and a lower surface of the second gate electrode.

In an example embodiment, the second gate electrode and the second gate insulation pattern may include or may be formed of materials substantially the same as materials of the first gate electrode 64 and the first gate insulation pattern 62. In an example embodiment, the source/drain region 87 may be a region doped with n-type impurities, e.g., phosphorus or arsenic. In example embodiments, the source/drain region 87 may have a doping concentration selected from a range of about 1017 cm⁻³ to about 1019 cm⁻³.

In example embodiments, the transistor may be a transistor included in an image sensor, such as a reset transistor, a source follower (SF) transistor, and a select transistor.

The FD region 85 may be disposed at an upper portion of the first substrate 10, that is, at a portion of the first substrate 10 adjacent to the first surface 12 of the first substrate 10, and may be disposed at an edge portion of the pixel region when viewed in a plan view. The FD region 85 may be adjacent to sidewalls of the first and second extension portions of the second isolation pattern 44. In an example embodiment, the FD region 85 may contact the sidewalls of the first and second extension portions of the second isolation pattern 44, however, the inventive concept may not be limited thereto. The FD region 85 may be spaced apart from the first impurity region 30 in the third direction D3. In some embodiment, the FD region 85 may be disposed in the p-type well of the first substrate 10.

In example embodiments, a recess 70 may be formed on the first surface 12 of the first substrate 10, and the FD region 85 may be disposed at a portion of the first substrate 10 under the recess 70. Thus, an upper surface of the FD region 85 may be exposed by the recess 70, and the upper surface of the FD region 85 may be disposed at a height lower than the first surface 12 of the first substrate 10 at which the recess 70 is not formed by a depth of the recess 70 in the third direction D3.

The FD region 85 may be a region doped with n-type impurities, e.g., phosphorus or arsenic. In example embodiments, the FD region 85 may have a doping concentration equal to or more than about 10¹⁵ cm⁻³. In example embodiments, the FD region 85 may have a doping concentration selected from a range of about 1017 cm⁻³ to about 1019 cm⁻³.

The TG structure 65, the light sensing element 50 and the FD region 85 may collectively form a transfer transistor. For example, the light sensing element 50 may serve as a source region of the transfer transistor, and the FD region 85 may serve as a drain region of the transfer transistor. The light sensing element 50 and the FD region 85 are regions doped with n-type impurities, and thus may be referred to as a first n-type impurity region and a second n-type impurity region, respectively.

The second impurity region 90 may be formed at the upper portion of the first substrate 10, that is, the portion of the first substrate 10 adjacent to the first surface 12 of the first substrate 10. In example embodiments, the second impurity region 90 may be disposed at a portion of the first substrate 10 between the TG structure 65 and the recess 70, and may contact sidewalls of the TG structure 65 and the recess 70. In an example embodiment, a lower surface of the second impurity region 90 may be higher than the upper surface of the FD region 85.

The second impurity region 90 may not overlap the FD region 85 in the third direction D3. The second impurity region 90 may overlap the light sensing element 50 in the third direction D3.

The second impurity region 90 may be a region doped with p-type impurities, e.g., boron, aluminum, or gallium. In example embodiments, the second impurity region 90 may have a doping concentration equal to or more than about 10¹⁸ cm⁻³.

In example embodiments, the FD region 85 may be disposed under the recess 70 in the first substrate 10, and thus the upper surface of the FD region 85 may be lower than the upper surface of the first substrate 10.

As the FD region 85 is disposed under the recess 70, a lower surface of the FD region 85 may be lower than a lower surface of a FD region that is disposed under the upper surface of the first substrate 10 on which no recess is formed, so that a distance between the FD region 85 and the light sensing element 50 may decrease. For example, compared to if a FD region is formed at the upper surface of the first substrate 10, the FD region 85 formed at the bottom surface of the recess 70 may have a shorter distance to the light sensing element 50. Thus, a charge transfer efficiency from the light sensing element 50 to the FD region 85 may be enhanced.

The second impurity region 90 is formed at the portion of the TG structure 65 and the FD region 85, so that an unnecessary path of charge from the light sensing element 50 to the FD region 85 may be blocked to maximize the charge transfer efficiency. For example, the second impurity region 90 may be formed in a region between the TG structure 65 and the FD region 85 to provide a charge transfer path from the light sensing element 50 to the FD region 85 via a channel formed by the TG structure 65. In some embodiments, the second impurity region 90 may be disposed in the p-type well.

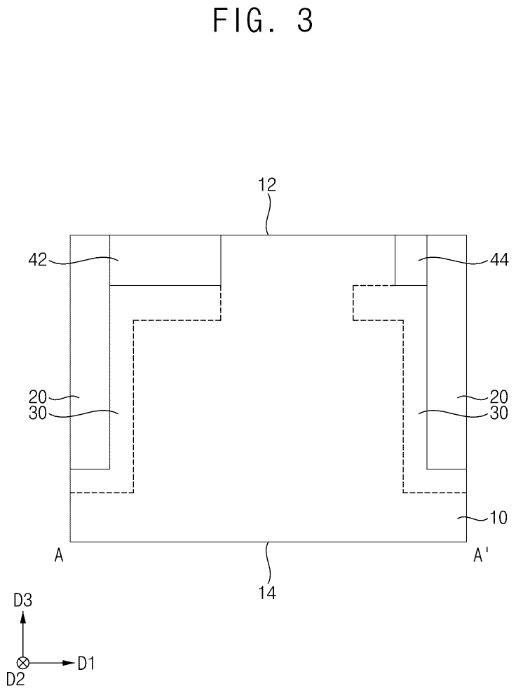

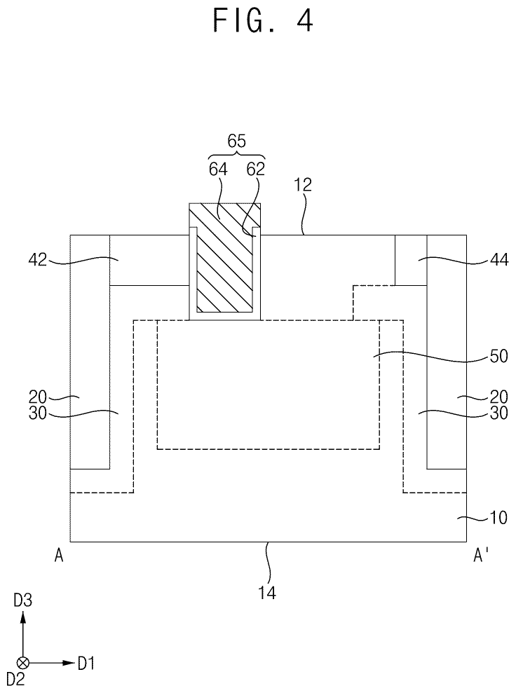

FIGS. 3 and 4 are cross-sectional views illustrating a method of forming a pixel of an image sensor in accordance with example embodiments, particularly, cross-sectional views taken along line A-A′ of FIG. 1.

Referring to FIG. 3, an upper portion of a first substrate 10 having a p-type well therein may be partially removed to form a first trench, and p-type impurities may be doped into a portion of the first substrate 10 adjacent to the first trench, so that a vertical extension portion and a second horizontal extension portion of a first impurity region 30 may be formed at portions of the first substrate 10 adjacent to a sidewall and a lower surface, respectively, of the first trench.

A pixel division pattern 20 may be formed in the first trench.

Upper portions of the first substrate 10 may be removed to form second and third trenches, respectively, and first and second isolation patterns 42 and 44 may be formed in the second and third trenches, respectively. In an example embodiment, when viewed in a plan view, the first isolation pattern 42 may be formed to extend in a direction having an acute angle with respect to the first and second directions D1 and D2 in a pixel region defined by the pixel division pattern 20, and the second isolation pattern 44 may be formed at an edge portion of the pixel region.

P-type impurities may be doped into a portion of the first substrate 10 under the first and second isolation patterns 42 and 44 to form a first horizontal extension portion of the first impurity region 30. In an example embodiment, the first horizontal extension portion of the first impurity region 30 may be formed to contact an upper portion of the vertical extension portion of the first impurity region 30. In an embodiment, the first horizontal extension portion may be connected to an upper end of the vertical extension portion.

Referring to FIG. 4, n-type impurities may be doped into the first substrate 10 to form a light sensing element 50. In some embodiments, the light sensing element 50 doped with the n-type impurities may be formed in the p-type well doped with p-type impurities.

In an example embodiment, the light sensing element 50 may be formed under the first horizontal extension portion of the first impurity region 30, and an upper surface of the light sensing element 50 may partially contact a lower surface of the first horizontal extension portion of the first impurity region 30. A lower surface of the light sensing element 50 may be higher than the lower surface of the pixel division pattern 20.

An upper portion of the first substrate 10 may be removed to form a fourth trench, and a TG structure 65 may be formed in the fourth trench. In example embodiments, the fourth trench may expose the upper surface of the light sensing element 50, and thus a lower surface of the TG structure 65 that may be formed in the fourth trench may contact the upper surface of the light sensing element 50. The TG structure 65 may include a first gate insulation pattern 62 and a first gate electrode 64.

When the fourth trench is formed, an upper portion of the first substrate 10 may also be removed to form a fifth trench, and when the TG structure 65 is formed, a gate structure 67 (refer to FIG. 1) may be formed in the fifth trench.

Referring to FIGS. 1 and 2, a recess 70 may be formed on the first substrate 10, and n-type impurities may be doped into a portion of the first substrate 10 under the recess 70 to form a FD region 85. In some embodiments, the FD region 85 doped with the n-type impurities may be formed in the p-type well.

In example embodiments, a lower surface of the FD region 85 may be spaced apart from an upper surface of the first impurity region 30 in the third direction D3.

In an example embodiment, when the FD region 85 is formed, n-type impurities may be doped into a portion of the first substrate 10 adjacent to the gate structure 67 to form a source/drain region 87.

P-type impurities may be doped into an upper portion of the first substrate 10 to form a second impurity region 90. In example embodiments, the second impurity region 90 may be formed at a portion of the first substrate 10 between the TG structure 65 and the recess 70, and may contact sidewalls of the TG structure 65 and the recess 70.

By the above processes, the pixel may be formed.

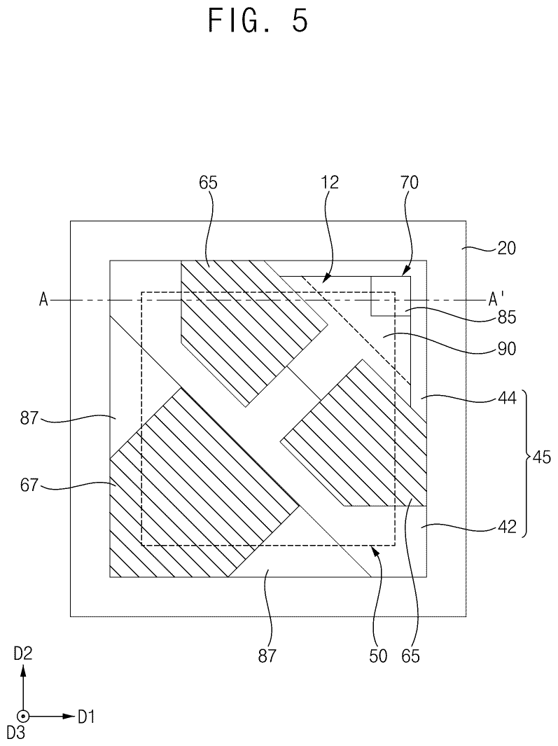

FIG. 5 is a plan view illustrating a pixel included in an image sensor, and FIG. 6 is a cross-sectional view taken along line A-A′ of FIG. 5.

This pixel may be substantially the same as or similar to that of FIGS. 1 and 2, except for the second impurity region 90, and thus repeated explanations are omitted herein.

Referring to FIGS. 5 and 6, the second impurity region 90 may not contact the sidewall of the TG structure 65. For example, the second impurity region 90 may be spaced apart from the sidewall of the TG structure 65, and a portion of the first substrate 10 may be disposed between the second impurity region 90 and the TG structure 65.

In some embodiments, the portion of the first substrate 10 may be undoped. In some embodiments, p-type impurities having a doping concentration less than about 10¹⁵ cm⁻³, or n-type impurities less than about 10¹⁵ cm⁻³ may be doped into the portion of the first substrate 10 between the second impurity region 90 and the TG structure 65.

As the second impurity region 90 and the TG structure 65 do not contact each other but are spaced apart from each other, abrupt change of energy band between the second impurity region 90 and the TG structure 65 may be relieved, so that leakage current and white spot may be reduced.

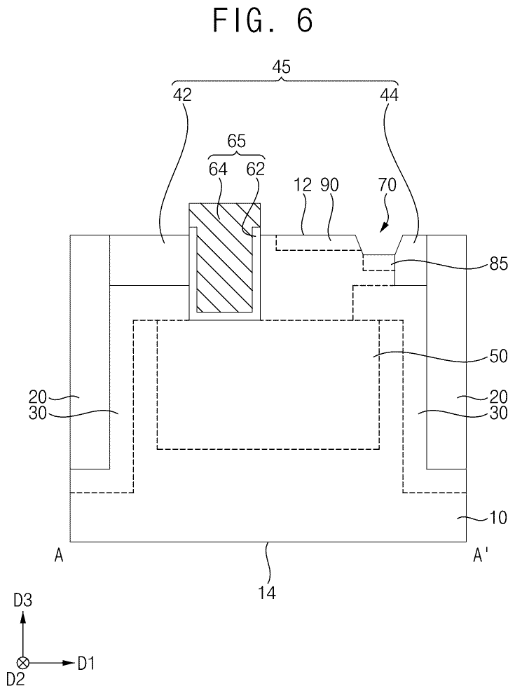

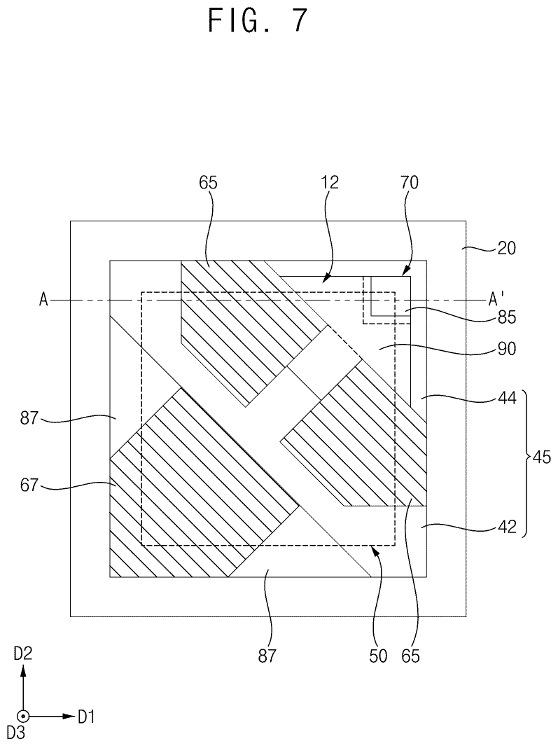

FIG. 7 is a plan view illustrating a pixel included in an image sensor, and FIG. 8 is a cross-sectional view taken along line A-A′ of FIG. 7.

This pixel may be substantially the same as or similar to that of FIGS. 1 and 2, except for the second impurity region 90, and thus repeated explanations are omitted herein.

Referring to FIGS. 7 and 8, the second impurity region 90 may not contact the sidewall of the recess 70. For example, the second impurity region 90 may be spaced apart from the sidewall of the recess 70, and a portion of the first substrate 10 may be disposed in a space between the second impurity region 90 and the sidewall of the recess 70.

In some embodiments, the portion of the first substrate 10 may be undoped. In some embodiments, p-type impurities having a doping concentration less than about 10¹⁵ cm⁻³, or n-type impurities less than about 10¹⁵ cm⁻³ may be doped into the portion of the first substrate 10 between the second impurity region 90 and the sidewall of the recess 70.

As the second impurity region 90 does not contact the sidewall of the recess 70, the second impurity region 90 may also be spaced apart from the FD region 85, which may reduce band-to-band tunneling between the second impurity region 90 and the FD region 85.

FIG. 9 is a cross-sectional view illustrating an image sensor in accordance with example embodiments. This image sensor may include the pixel illustrated with reference to FIGS. 1 and 2, except that the vertical direction is opposite, and thus repeated explanations are omitted herein.

Referring to FIG. 9, the image sensor may include a second substrate 300, a second insulating interlayer 320, a first insulating interlayer 140, the first substrate 10 and a lower planarization layer 770 sequentially stacked in a reverse direction to the third direction D3 in first, second, third and fourth regions I, II, III and IV.

A color filter array layer 230, a microlens 240 and a transparent protection layer 650 may be sequentially stacked on the lower planarization layer 770 in the first region I, a light blocking layer 620, an upper planarization layer 640 and the transparent protection layer 650 may be sequentially stacked on the lower planarization layer 770 in the second and third regions II and III, and the upper planarization layer 640 and the transparent protection layer 650 may be sequentially stacked on the lower planarization layer 770 in the fourth region IV.

The image sensor may further include first to third wirings 122, 124 and 135 and first and second vias 112 and 114 disposed in the first insulating interlayer 140, the pixel division pattern 20 extending through the first substrate 10 in the third direction D3, the first impurity region 30, the isolation structure 45, the light sensing element 50, the TG structure 65, the gate structure 67 (refer to FIG. 1), the FD region 85, the source/drain region 87 (refer to FIG. 1) and the second impurity region 90 in the first and second regions I and II.

The image sensor may further include an interference blocking structure 200 between neighboring ones of first to third color filters 222, 224 and 226 that are included in the color filter array layer 230 and a protection layer 210 on the lower planarization layer 770 and covering a surface of the interference blocking structure 200 in the first region I.

The image sensor may further include a fourth wiring 137 disposed in the first insulating interlayer 140, a fifth wiring 310 disposed in the second insulating interlayer 320, and a first through via structure extending through the lower planarization layer 770, the first substrate 10, the first insulating interlayer 140 and an upper portion of the second insulating interlayer 320 to commonly contact the fourth and fifth wirings 137 and 310 in the third region III.

The image sensor may further include the fifth wiring 310 disposed in the second insulating interlayer 320, a pad 510 extending through the lower planarization layer 770 and an upper portion of the first substrate 10, a second through via structure extending through the lower planarization layer 770, the first substrate 10, the first insulating interlayer 140 and an upper portion of the second insulating interlayer 320 to contact the fifth wiring 310 in the fourth region IV.

In example embodiments, the first region I may have a shape of a square or a rectangle when viewed in a plan view, the second region II may surround the first region I, the fourth region IV may surround the second region II, and the third region III may be disposed in the fourth region IV, however, the inventive concept may not be limited thereto.

In example embodiments, the first region I may be an active pixel region in which active pixels are formed, the second region II may be an optical black (OB) region in which OB pixels are formed, the third region III may be a stack region in which the first through via structure is formed, and the fourth region IV may be a pad region in which the pads 510 are formed.

The first substrate 10 may include the first and second surfaces 12 and 14 opposite to each other in the third direction D3, and the second substrate 300 may include third and fourth surfaces 302 and 304 opposite to each other in the third direction D3. FIG. 9 shows that the first surface 12 is disposed under the second surface 14, and the third surface 302 is disposed over the fourth surface 304.

The first via 112 may contact the TG structure 65, and may be connected to the first wiring 122. The second via 114 may contact the FD region 85, and may be connected to the second wiring 124. The third wiring 135 is disposed under the second wiring 124, and the fourth wiring 137 may be disposed at the same level as and a lower level than the third wiring 135.

Vias and wirings connected to transistors in each pixel region may be further formed in the first insulating interlayer 140 in the first and second regions I and II. FIG. 9 shows that the fourth and fifth wirings 137 and 310 are disposed at second and third levels, respectively, in the third direction D3, however, the inventive concept may not be limited thereto.

Each of the first and second insulating interlayers 140 and 320 may include oxide, e.g., silicon oxide or a low-k dielectric material having a dielectric constant lower than that of silicon oxide.

In an example embodiment, the lower planarization layer 770 may include first, second, third, fourth and fifth layers 720, 730, 740, 750 and 760 sequentially stacked in the reverse direction to the third direction D3. For example, the first to fifth layers 720, 730, 740, 750 and 760 may include or may be formed of aluminum oxide, hafnium oxide, silicon oxide, silicon nitride and hafnium oxide, respectively. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The interference blocking structure 200 may serve as a fence for blocking a light incident into a pixel from travelling into a neighboring pixel to block light interference. The interference blocking structure 200 may overlap the pixel division pattern 20 in the third direction D3.

In an example embodiment, the interference blocking structure 200 may include first and second interference blocking patterns 180 and 190 stacked in the reverse direction to the third direction D3. The first interference blocking pattern 180 may include or may be formed of a metal nitride, e.g., titanium nitride, and the second interference blocking pattern 190 may include or may be formed of metal having a low light absorption rate, e.g., tungsten, or a lower refractive index material (LRIM), e.g., porous silicon oxide. In an example embodiment, the interference blocking structure 200 may have a single layer structure including a transparent material having a low refractive index.

The protection layer 210 may include or may be formed of a metal oxide, e.g., aluminum oxide.

The color filter array layer 230 may be formed on the protection layer 210, and thus a lower surface and a sidewall of each of the first to third color filters 222, 224 and 226 included in the color filter array layer 230 may be covered by the protection layer 210. Each of the first to third color filters 222, 224 and 226 may be a film formed by depositing a composition that may be formed by mixing a pigment, a pigment dispersant, a binder resin and a solvent.

The light blocking layer 620 may have the same composition as the second color filter 224, which may absorb a light having a relatively large wavelength among the first to third color filters 222, 224 and 226.

The light blocking layer 620 may be formed on the lower planarization layer 770, the first through via structure and an insulation pattern 530 in the second and third regions II and III of the first substrate 10. The light blocking layer 620, however, may not be formed on a portion of the insulation pattern 530 on a seventh trench 520, which may be formed by partially removing a portion of a conductive pattern 500 on the lower planarization layer 770 at a boundary of the third and fourth regions III and IV to expose an upper surface of the lower planarization layer 770.

The first through via structure may include a first filling pattern 540 extending in the third direction D3 through the lower planarization layer 770, the first substrate 10, the first insulating interlayer 140 and an upper portion of the second insulating interlayer 320, the insulation pattern 530 covering a lower surface and a sidewall of the first filling pattern 540, the conductive pattern 500 covering a lower surface and a sidewall of the insulation pattern 530, and a first capping pattern 545 on an upper surface of the first filling pattern 540.

The second through via structure may include a second filling pattern 550 extending in the third direction D3 through the lower planarization layer 770, the first substrate 10, the first insulating interlayer 140 and an upper portion of the second insulating interlayer 320, the insulation pattern 530 covering a lower surface and a sidewall of the second filling pattern 550, the conductive pattern 500 covering a lower surface and a sidewall of the insulation pattern 530, and a second capping pattern 555 on an upper surface of the second filling pattern 550.

Each of the first and second filling patterns 540 and 550 may include or may be formed of, e.g., a low refractive index material (LRIM), and each of the first and second capping patterns 545 and 555 may include or may be formed of, e.g., a photoresist material.

A portion of the conductive pattern 500 included in the first through via structure may commonly contact the fourth and fifth wirings 137 and 310 so that the fourth and fifth wirings 137 and 310 may be electrically connected with each other, and a portion of the conductive pattern 500 included in the second through via structure may contact the fifth wiring 310 to be electrically connected thereto. The conductive pattern 500 may be included in the first and second through via structures, and may also be formed on the lower planarization layer 770 in the second to fourth regions II, III and IV.

The conductive pattern 500 may include or may be formed of metal, e.g., tungsten. In an example embodiment, a barrier pattern (not shown) including a metal nitride, e.g., titanium nitride may be further formed under the conductive pattern 500.

The insulation pattern 530 may be included in the first and second through via structures, and may also be formed on the portion of the conductive pattern 500 on the lower planarization layer 770 in the second to fourth regions II, III and IV. As illustrated above, the insulation pattern 530 may also be formed on the seventh trench 520 exposing the upper surface of the lower planarization layer 770 to partially contact the lower planarization layer 770. The insulation pattern 530 may include or may be formed of oxide, e.g., silicon oxide.

The pad 510 may be electrically connected to an outer wiring, and may be a path through which electrical signals may be input into the active pixels and/or the OB pixels, or electrical signals may be output from the active pixels and/or the OB pixels. The pad 510 may include or may be formed of metal, e.g., aluminum. A lower surface and a sidewall of the pad 510 may be covered by the conductive pattern 500.

The microlens 240 may be formed on the color filter array layer 230 and the protection layer 210 in the first region I. The upper planarization layer 640 may be formed on the light blocking layer 620, the insulation pattern 530 and the second through via structure in the second to fourth regions II, III and IV. The upper planarization layer 640 may include a second opening 660 exposing an upper surface of the pad 510 in the fourth region IV. In example embodiments, the microlens 240 and the upper planarization layer 640 may include or may be formed of substantially the same material, e.g., a photoresist material having a high transmittance.

The transparent protection layer 650 may be formed on the microlens 240 and the upper planarization layer 640. The transparent protection layer 650 may include or may be formed of, e.g., SiO, SiOC, SiC, or SiCN.

The image sensor may include the pixel as shown in FIGS. 1 and 2. The pixel of FIGS. 1 and 2 is overturned (i.e., turned upside down) to form the pixel in FIG. 9, which may have the following structure.

The light sensing element 50 may be formed in an upper portion of the first substrate 10. The TG structure 65 may extend in the third direction D3 through a lower portion of the first substrate 10, and may be adjacent to or contact a lower surface of the light sensing element. The FD region 85 may be disposed under and spaced apart from the light sensing element 50 in the third direction D3 in the first substrate 10, and may be spaced apart from the TG structure 65 in the horizontal direction. The second impurity region 90 may be disposed under the FD region 85 in the first substrate 10, and may be disposed in a space between the TG structure 65 and the FD region 85. The second impurity region 90 may not overlap the FD region 85 in the third direction D3, and may overlap the light sensing element 50.

In example embodiments, the lower surface of the FD region 85 may be higher than a lower surface and an upper surface of the second impurity region 90.

As illustrated above, in each pixel in accordance with example embodiments, the distance between the light sensing element 50 and the FD region 85 may decrease to enhance the charge transfer efficiency. Such enhanced charge transfer efficiency may improve electrical characteristics of the image sensor.

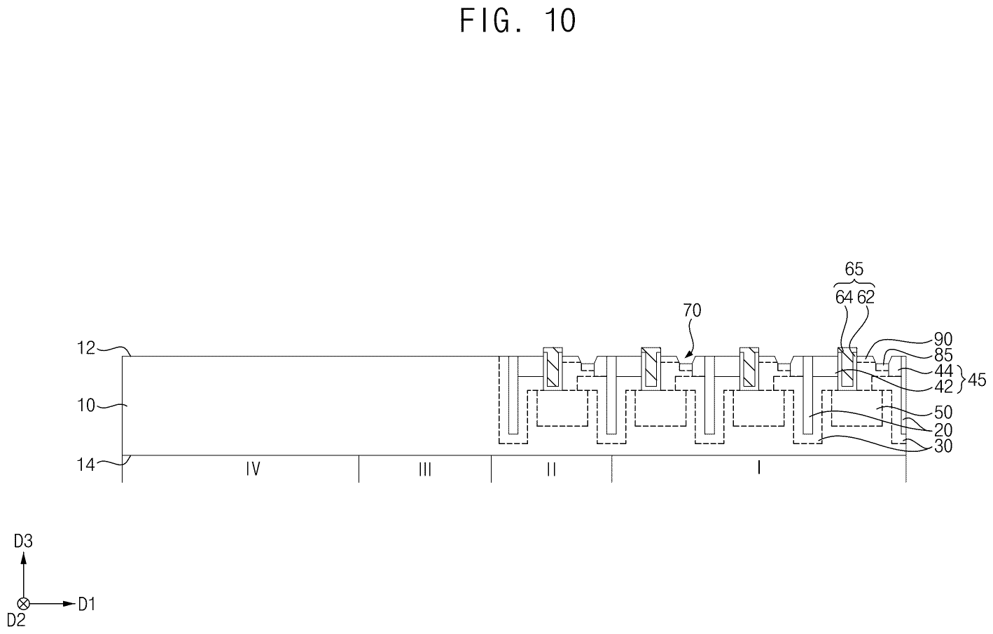

FIGS. 10 to 16 are cross-sectional views illustrating a method of manufacturing an image sensor in accordance with example embodiments.

Referring to FIG. 10, the structures as shown in FIGS. 1 and 2, particularly, the pixel division pattern 20, the first impurity region 30, the isolation structure 45, the light sensing element 50, the TG structure 65, the gate structure 67 (refer to FIG. 1), the recess 70, the FD region 85, the source/drain region 87 (refer to FIG. 1) and the second impurity region 90 may be formed in the first and second regions I and II of the first substrate 10 including the first to fourth regions I, II, III and IV and having the first and second surfaces 12 and 14 opposite to each other in the third direction D3.

Referring to FIG. 11, first and second vias 112 and 114 and first to fourth wirings 122, 124, 135 and 137 may be formed on the first substrate 10, and a first insulating interlayer 140 may be formed on the first substrate 10 to cover the first and second vias 112 and 114 and the first to fourth wirings 122, 124, 135 and 137.

The first and second vias 112 and 114 and the first to third wirings 122, 124 and 135 may be formed in the first and second regions I and II of the first substrate 10, and the fourth wiring 137 may be formed in the third region III of the first substrate 10.

In example embodiments, the first and second vias 112 and 114 and the first to fourth wirings 122, 124, 135 and 137 may be formed by a dual damascene process or a single damascene process.

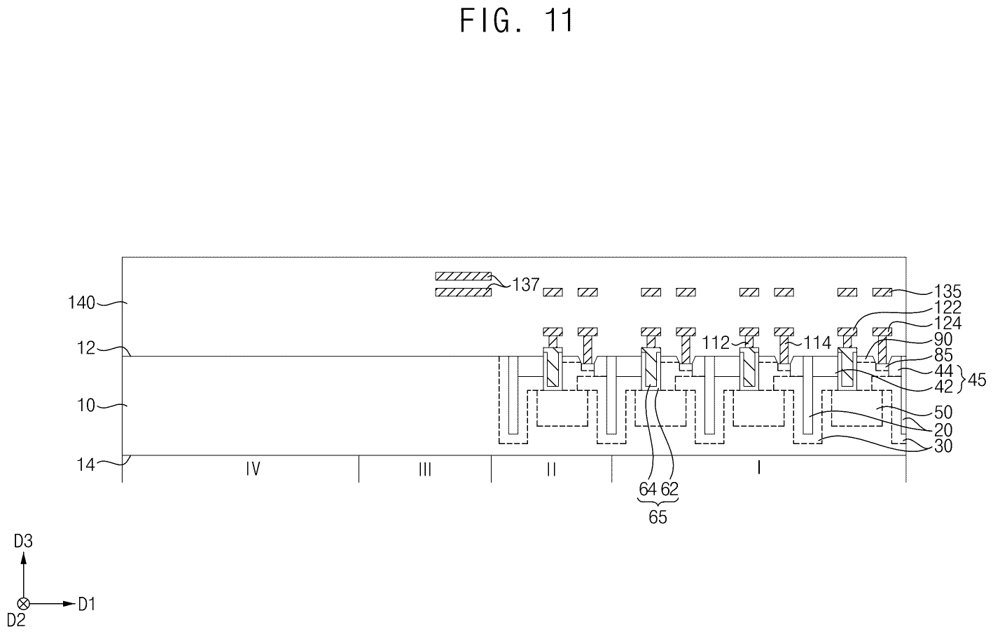

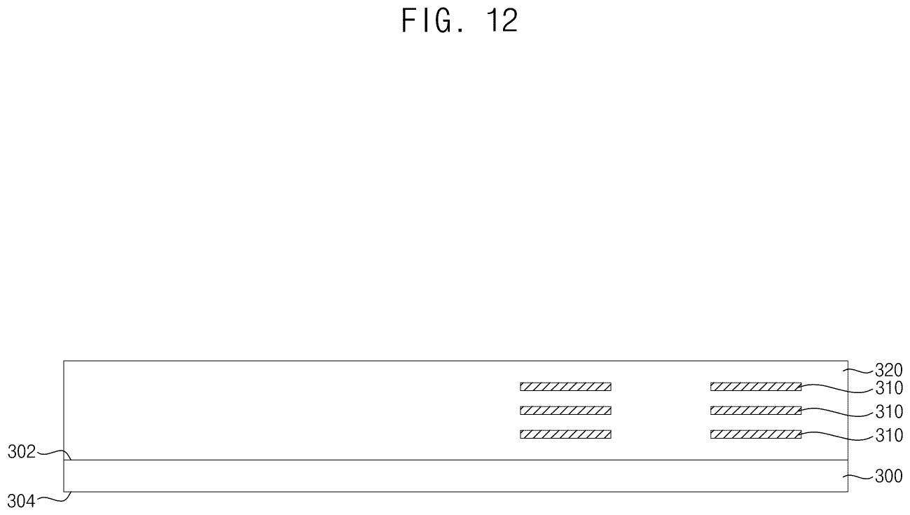

Referring to FIG. 12, fifth wirings 310 may be formed on a third surface 302 of a second substrate 300 including the third surface 302. The second substrate 300 may have a fourth surface 304 opposite thereto, and a second insulating interlayer 320 may be formed on the second substrate 300 to cover the fifth wirings 310.

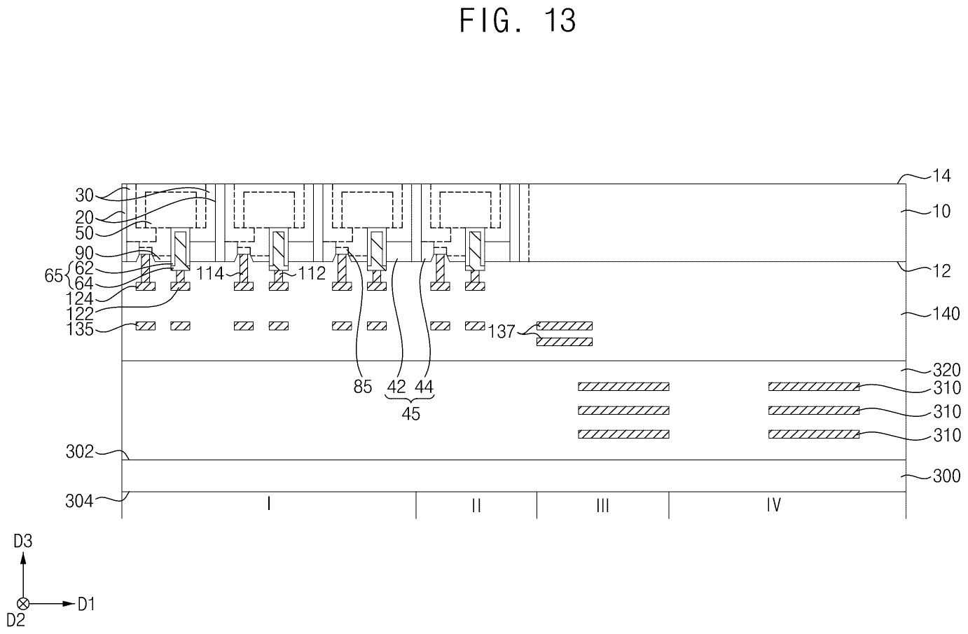

Referring to FIG. 13, the first insulating interlayer 140 on the first substrate 10 and the second insulating interlayer 320 on the second substrate 300 may be bonded with each other, and a portion of the first substrate 10 adjacent to the second surface 14 may be removed.

In example embodiments, the first and second insulating interlayers 140 and 320 may be bonded through a bonding layer (not shown). In an example embodiment, the first and second insulating interlayers 140 and 320 may be bonded with no bonding layer. After bonding the first and second insulating interlayers 140 and 320, the bonded structure may be overturn (i.e., turned upside down) so that the second surface 14 of the first substrate 10 may face upward, and hereinafter, the bonded structure will be explained with the second surface 14 of the first substrate 10 facing upward.

As the first and second substrates 10 and 300 are bonded with each other, the fifth wirings 310 on the second substrate 300 may be disposed in the third and fourth regions III and IV of the first substrate 10.

In example embodiments, the portion of the first substrate 10 adjacent to the second surface 14 may be removed by a polishing process, e.g., a grinding process. Thus, in the polishing process, an upper surface of the pixel division pattern 20 may be exposed, and the second horizontal extension portion of the first impurity region 30 may be removed.

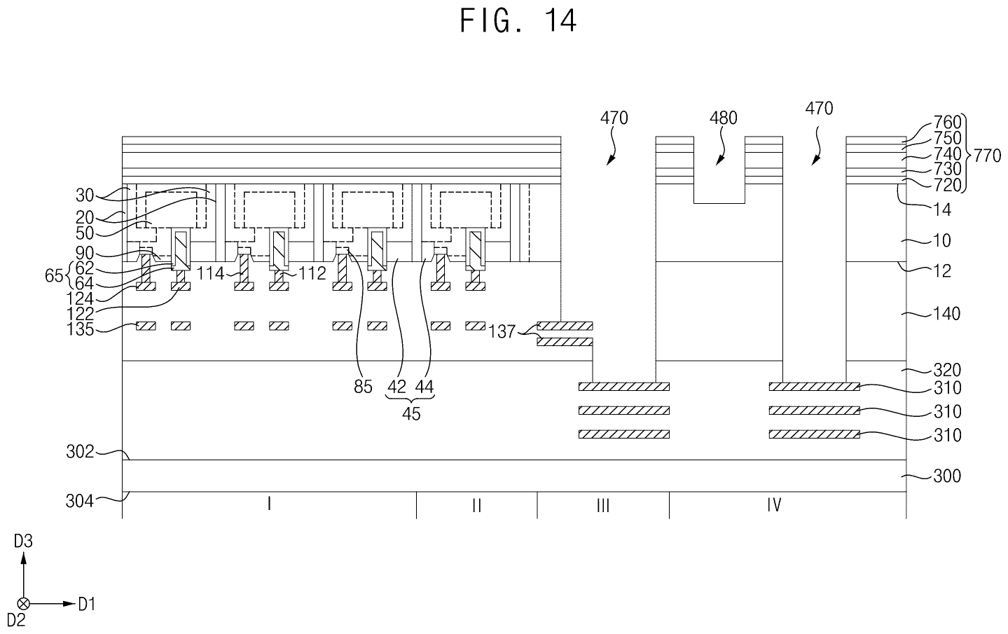

Referring to FIG. 14, a lower planarization layer 770 may be formed on the second surface 14 of the first substrate 10.

In an example embodiment, the lower planarization layer 770 may include first to fifth layers 720, 730, 740, 750 and 760 sequentially stacked in the third direction D3.

The lower planarization layer 770, the first substrate 10, the first insulating interlayer 140 and an upper portion of the second insulating interlayer 320 in the third and fourth regions III and IV of the first substrate 10 may be partially removed to form a first opening 470. The lower planarization layer 770 and an upper portion of the first substrate 10 in the fourth region IV may be removed to form a sixth trench 480.

The first opening 470 in the third region III of the first substrate 10 may expose the fourth wiring 137 in the first insulating interlayer 140 and the fifth wiring 310 in the second insulating interlayer 320, and the first opening 470 in the fourth region IV of the first substrate 10 may expose the fifth wiring 310 in the second insulating interlayer 320.

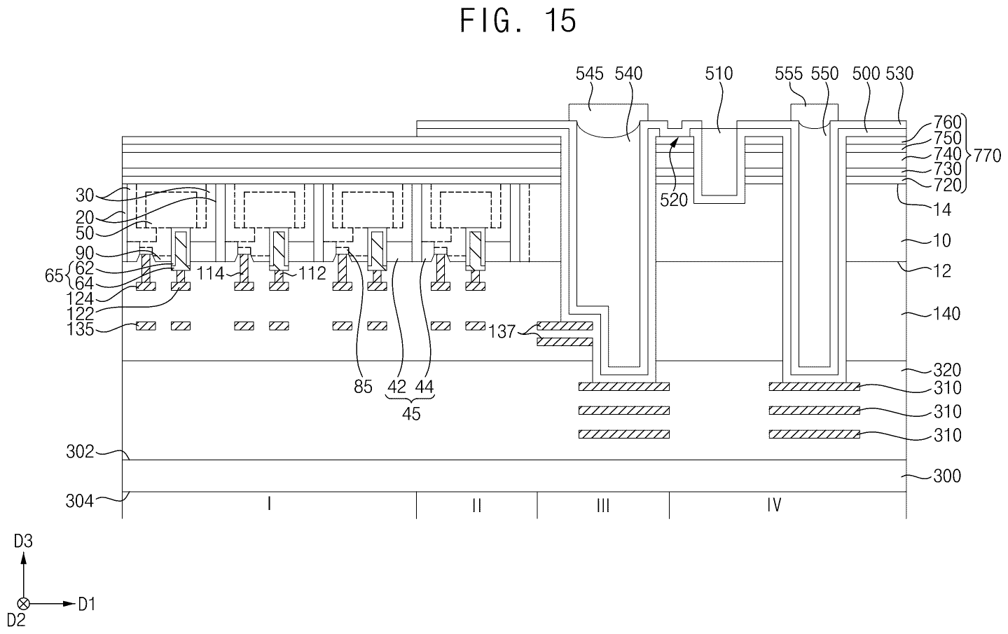

Referring to FIG. 15, a first conductive layer may be formed on bottoms and sidewalls of the first opening 470 and the sixth trench 480 and an upper surface of the lower planarization layer 770, a second conductive layer may be formed on the first conductive layer to fill the sixth trench 480, and an upper portion of the second conductive layer may be exposed until an upper surface of the first conductive layer is exposed.

Thus, a pad 510 may be formed on the first conductive layer in the sixth trench 480 which is formed in the fourth region IV of the first substrate 10.

The planarization process may be performed by, e.g., a chemical mechanical polishing (CMP) process and/or an etch back process.

Before forming the first conductive layer, a barrier layer may be further formed on the bottoms and sidewalls of the first opening 470 and the sixth trench 480 and the upper surface of the lower planarization layer 770.

The first conductive layer may be partially removed at a boundary area between the third and fourth regions III and IV of the first substrate 10 to form a seventh trench 520 exposing an upper surface of the lower planarization layer 770.

An insulation layer may be formed on upper surfaces of the first conductive layer and the pad 510 and a bottom and a sidewall of the seventh trench 520, a filling layer may be formed on the insulation layer to fill the first openings 470, and an upper portion of the filling layer may be planarized until an upper surface of the insulation layer is exposed.

An additional etching process may be performed on the filling layer so that a portion of the filling layer in the seventh trench 520 may be removed, and thus a first filling pattern 540 may be formed on the insulation layer in the first opening 470 in the third region III of the first substrate 10, and a second filling pattern 550 may be formed on the insulation layer in the first opening 470 which is disposed in the fourth region IV of the first substrate 10.

A capping layer may be formed on the first and second filling patterns 540 and 550 and the insulation layer, and patterned to form first and second capping patterns 545 and 555 on the first and second filling patterns 540 and 550, respectively.

A portion of the insulation layer in the first region I of the first substrate 10 and a portion of the insulation layer on the upper surface of the pad 510 may be removed to form an insulation pattern 530, and a portion of the first conductive layer in the first region I of the first substrate 10 may be removed to form a conductive pattern 500. Thus, the upper surface of the lower planarization layer 770 in the first region I of the first substrate 10 may be exposed.

If the barrier layer is formed under the first conductive layer, the barrier layer may also be partially removed when the portion of the first conductive layer is removed to form a barrier pattern.

A portion of the conductive pattern 500 and the insulation pattern 530 in the first opening 470, and the first filling pattern 540 and the first capping pattern 545 in the third region III of the first substrate 10 may collectively form a first through via structure. A portion of the conductive pattern 500 and the insulation pattern 530 in the first opening 470, the second filling pattern 550 and the second capping pattern 555 in the fourth region IV of the first substrate 10 may collectively form a second through via structure.

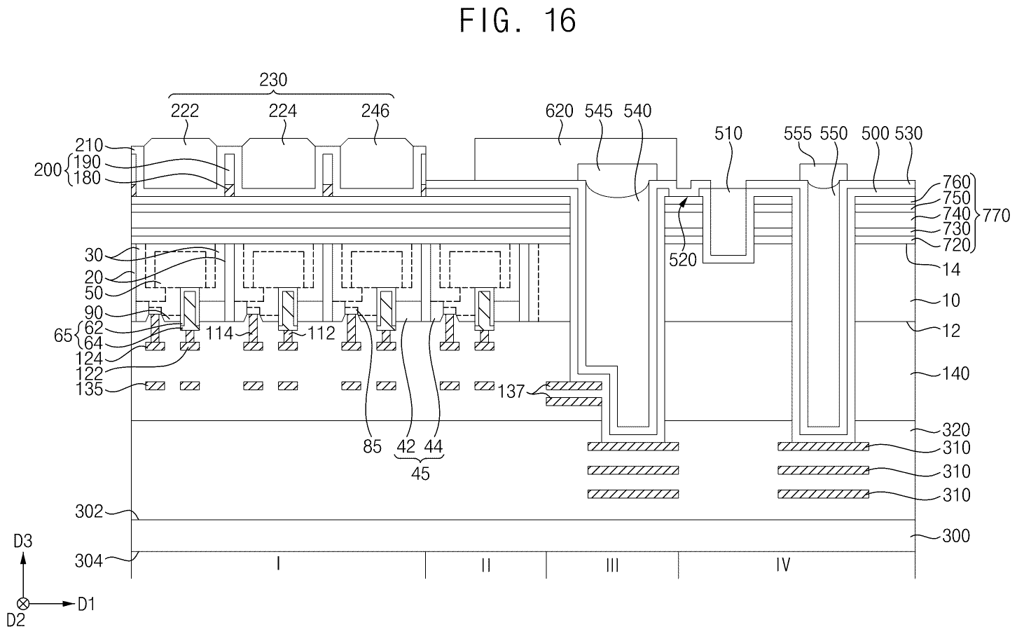

Referring to FIG. 16, an interference blocking structure 200 may be formed on the upper surface of the lower planarization layer 770 in the first region I of the first substrate 10, and a protection layer 210 may be formed on the lower planarization layer 770 and the interference blocking structure 200.

The interference blocking structure 200 may be formed to overlap each of the pixel division patterns 20 in the third direction D3.

A color filter array layer 230 may be formed on the protection layer 210 in the first region I of the first substrate 10, and a light blocking layer 620 may be formed on the insulation pattern 530 and the first capping pattern 545 in the second and third regions II and III of the first substrate 10.

In example embodiments, a first color filter 222 may be formed in a first portion of an area that may be defined by the interference blocking structure 200, a second color filter 224 may be formed in a second portion of the area, and a third color filter 226 may be formed in a third portion of the area. The first to third color filters 222, 224, and 226 may constitute the color filter array layer 230. Each of the first to third color filters 222, 224 and 226 may be formed by depositing a color filter layer and performing an exposure process and a developing process on the color filter layer.

For example, when the second color filter 224 is formed, the light blocking layer 620 including the same composition as the second color filter 224 may be formed on the lower planarization layer 770, the first capping pattern 545 and the insulation pattern 530 in the second region II of the first substrate 100. The light blocking layer 620 may not be formed on a portion of the insulation pattern 530 in the seventh trench 520 (refer to FIG. 15).

Referring to FIG. 9, an upper planarization layer 640 may be formed on the color filter array layer 230, the protection layer 210, the light blocking layer 620, the insulation pattern 530, the pad 510 and the second capping pattern 555 in the first to fourth regions I, II, III and IV of the first substrate 10. A patterning process and a reflow process may be performed on the upper planarization layer 640 in the first region I of the first substrate 10 to form a microlens 240.

A transparent protection layer 650 may be formed on the microlens 240 and the upper planarization layer 640, and a portion of the transparent protection layer 650 overlapping the pad 510 in the fourth region IV of the first substrate 10 and a portion of the upper planarization layer 640 thereunder may be removed to form a second opening 660 exposing an upper surface of the pad 510.

An upper wiring (not shown) may be formed to be electrically connected to the pad 510 so that the fabrication of the image sensor may be completed.

As described above, although the present invention has been described with reference to example embodiments, those skilled in the art will readily appreciate that many modifications are possible in the example embodiments without materially departing from the novel teachings and advantages of the present inventive concept.

What is claimed is:

1. An image sensor comprising:
a photodiode disposed in a substrate and including an n-type impurity region, wherein the n-type impurity region is doped with n-type impurities;
a transfer gate (TG) structure partially buried in the substrate and disposed on the n-type impurity region;
a recess disposed at an upper surface of the substrate and being spaced apart from the TG structure;
a floating diffusion (FD) region disposed under the recess and doped with n-type impurities; and
an impurity region disposed at a portion of the substrate between the TG structure and the recess and doped with p-type impurities,
wherein an upper surface of the FD region is lower than an upper surface of the impurity region.

2. The image sensor of claim 1,
wherein the upper surface of the FD region is lower than a lower surface of the impurity region.

3. The image sensor of claim 1,
wherein the impurity region contacts a sidewall of the TG structure.

4. The image sensor of claim 1,
wherein the impurity region is spaced apart from the TG structure.

5. The image sensor of claim 4,
wherein a first portion of the substrate between the impurity region and the TG structure is undoped or doped with p-type impurities or n-type impurities at a doping concentration that is less than about 10¹⁵ cm⁻³.

6. The image sensor of claim 5,
wherein the impurity region contacts a sidewall of the recess.

7. The image sensor of claim 1,
wherein the impurity region is spaced apart from a sidewall of the recess.

8. The image sensor of claim 7,
wherein a second portion of the substrate between the impurity region and the recess is undoped or doped with p-type impurities or n-type impurities at a doping concentration that is less than about 10¹⁵ cm⁻³.

9. The image sensor of claim 1, further comprising:
a well disposed in the substrate,
wherein the well is doped with p-type impurities at a doping concentration less than about 10¹⁵ cm⁻³ and the n-type impurity region is disposed in the well.

10. An image sensor comprising:
a first n-type impurity region in a substrate;
a transfer gate (TG) structure partially buried in an upper portion of the substrate in a vertical direction perpendicular to an upper surface of the substrate and disposed on an upper surface of the first n-type impurity region;
a second n-type impurity region disposed in the substrate, wherein the second n-type impurity region is disposed over and spaced apart from the first n-type impurity region in the vertical direction, and wherein the second n-type impurity region is spaced apart from the TG structure in a horizontal direction parallel to the upper surface of the substrate; and
a p-type impurity region in the upper portion of the substrate and doped with p-type impurities,
wherein an upper surface of the second n-type impurity region is lower than a lower surface of the p-type impurity region.

11. The image sensor of claim 10,
wherein, when viewed in a plan view, the second n-type impurity region is spaced apart from the p-type impurity region.

12. The image sensor of claim 10,
wherein the first n-type impurity region and the p-type impurity region overlap each other in the vertical direction.

13. The image sensor of claim 10, further comprising:
a well disposed in the substrate and doped with p-type impurities at a doping concentration less than about 10¹⁵ cm⁻³, wherein the first and second n-type impurity regions and the p-type impurity region are disposed in the well.

14. The image sensor of claim 10,
wherein the p-type impurity region contacts a sidewall of the TG structure.

15. The image sensor of claim 10,
wherein the p-type impurity region is spaced apart from the TG structure.

16. An image sensor comprising:
a microlens on an upper surface of a substrate;
a color filter array layer disposed between the upper surface of the substrate and the microlens;
a first n-type impurity region in the substrate;
a transfer gate (TG) structure partially buried in a lower portion of the substrate in a vertical direction perpendicular to the upper surface of the substrate, wherein the TG structure is disposed under the first n-type impurity region;
a second n-type impurity region disposed in the substrate, wherein the second n-type impurity region is positioned lower than and spaced apart from the first n-type impurity region in the vertical direction, and wherein the second n-type impurity region is spaced apart from the TG structure in a horizontal direction parallel to the upper surface of the substrate; and
a p-type impurity region disposed in the substrate and positioned lower than the second n-type impurity region,
wherein an upper surface of the second n-type impurity region is higher than an upper surface of the p-type impurity region.

17. The image sensor of claim 16,
wherein, when viewed in a plan view, the second n-type impurity region is spaced apart from the p-type impurity region.

18. The image sensor of claim 16,
wherein the first n-type impurity region and the p-type impurity region overlap each other in the vertical direction.

19. The image sensor of claim 10, further comprising
a well disposed in the substrate and doped with p-type impurities at a doping concentration less than about 10¹⁵ cm⁻³, wherein the first and second n-type impurity regions and the p-type impurity region are disposed in the well.

20. The image sensor of claim 16,
wherein the p-type impurity region is spaced apart from the TG structure.
